(19) United States
(12) Patent Application Publication
(10) Pub. No.: US 2006/0087380 A1
(43) Pub. Date: Apr. 27, 2006

(54) Method for limiting the dynamic range of audio signals, and circuit arrangement for this purpose

(76) Inventor: Volker Hohmann, Oldenburg (DE)

Correspondence Address: WHITHAM, CURTIS & CHRISTOFFERSON, P.C., 11491 SUNSET HILLS ROAD, SUITE 340, RESTON, VA, 20190, US

(21) Appl. No.: 11/223,204

(22) Filed: Sep. 12, 2005

(30) Foreign Application Priority Data
Sep. 15, 2004 (DE) 10 2004 044 565.6

(51) Int. Cl. H03G 7/00

(52) U.S. Cl. 333/14

(57) ABSTRACT

A method for limiting the dynamic range of audio signals (S) provides for control of the dynamic range limiting on the basis of the instantaneous frequency of the audio signal (S) which is to be compressed as a control parameter.

The invention relates to a method for limiting the dynamic range of audio signals.

The invention also relates to a circuit arrangement for limiting the dynamic range of audio signals with at least one automatic dynamic range control unit.

One great problem for people with hearing difficulties is the reduced remaining dynamic range of the ear between the threshold of hearing and the unpleasant level of hearing.

The remaining dynamic range is essentially dependent on the signal frequency, i.e. the remaining range is generally smaller the greater the loss of hearing at a particular frequency.

To compensate, the wide range of signal levels, particularly the range of signal levels which arises in the audio environment and which is processed by the normal hearing system, needs to be compressed into the individual remaining dynamic range of the ear of an individual person with hearing difficulties. The compression means control the gain level which is applied to the input signal, so that the gain decreases as signal amplitude increases. Since the remaining dynamic range is dependent on frequency, the dynamic range compression system should split the audio signal into various frequency bands and should use different compression factors in the different frequency bands.

U.S. Pat. No. 5,500,902 A1 describes such a circuit arrangement for limiting the dynamic range of audio signals with a plurality of bandpass filters connected in parallel and respective downstream automatic gain controllers.

Similarly, US 2002-0,057,808 A1 describes a hearing amplifier with rapid dynamic range control in subbands and adaptive control of the compression threshold.

Plomp, R., “The negative effect of amplitude compression in multichannel hearing aids in the light of the modulation-transfer function”, in: Journal of the Acoustical Society of America, 83(6), June 1988, pages 2322 to 2327, describes the averaging of the gain control over time to improve audio quality. This measure is based on the observation that rapid multifrequency-band dynamic range compression without averaging over time or with short average time constants reduces the voice amplitude modulation, which is considered to be important for speech intelligibility.

The use of time averages smoothes out the time variations in the gain and therefore preserves modulations, while interference is avoided.

In addition, U.S. Pat. No. 6,198,830 B1 discloses a circuit arrangement for limiting the dynamic range of audio signals in which an automatic gain controller is controlled on the basis of results of signal analyses in order to align the gain control system with different audio environments. In this case, longer time axes are taken into account, i.e. the dynamic range limiting is switched from a noisy to a quiet environment, for example. There is no short-term control.

Douglas, J. Nelson, “Cross-spectral methods for processing speech”, in: Journal of Acoustics Society of America, 110(5), November 2001, pages 2575 to 2592 discloses the determination of an instantaneous frequency, of a channelized instantaneous frequency and of a local group delay in order to analyze nonstationary multicomponent FM signals.

In addition, Christian Giguere and Philip C. Woodland “A computational model of the auditory periphery for speech and hearing research. I. Ascending path” in: Journal Acoustic Society of America, 95(1), January 1994, pages 331 to 342, describes the modeling of the human peripheral hearing, particularly of the cochlear function.

Against this background, it is an object of the invention to provide an improved method for limiting the dynamic range of audio signals which optimizes the adjustment of the dynamic range particularly for speech processing in hearing aids and for improving automatic speech recognition.

The invention achieves the object with a method for limiting the dynamic range of audio signals by virtue of the dynamic range limiting being controlled on the basis of the instantaneous frequency of the audio signal which is to be compressed as a control parameter.

It has been found that audio quality can be significantly improved in comparison with the usual control variables by using the instantaneous frequency, i.e. the audio signal's instantaneous frequency which is currently present at the time of measurement and control.

In particular, the inventive control method, in contrast to the conventional methods for dynamic range control, permits quasi-instant compression with high perceptive signal quality and is approximately equivalent to reconstruction of a time signal from the simulated stimulation of the cochlea in a person with normal hearing.

The instantaneous frequency is preferably used to control a gain factor, a compression ratio and/or an adaptation time constant for an automatic gain controller AGC.

In this case, the adaptation time constants for limiting dynamic range should be less than 20 ms.

It is particularly advantageous to have parallel control of the dynamic range limiting for a plurality of band-limited audio signals.

It is also an object of the invention to produce an improved circuit arrangement for limiting the dynamic range of audio signals with at least one automatic dynamic range control unit.

The invention achieves the object with the circuit arrangement of the generic type by virtue of at least one unit for ascertaining the instantaneous frequency, said unit being connected to the at least one dynamic range control unit in order to control the dynamic range limiting on the basis of the ascertained instantaneous frequency.

It is particularly advantageous if a plurality of bandpass filters are provided for the audio signal whose dynamic range is to be limited and a respective automatic gain control unit is arranged at the output of an associated bandpass filter. In this case, a respective unit for ascertaining the instantaneous frequency of the bandpass-filtered audio signal should be connected to the output of the associated bandpass filter and should be coupled to the associated automatic gain control unit in order to limit the dynamic range of the bandpass-filtered audio signal on the basis of the instantaneous frequency of the bandpass-filtered audio signal as a control parameter.

The invention is explained in more detail by way of example below with reference to the appended drawings, in which:

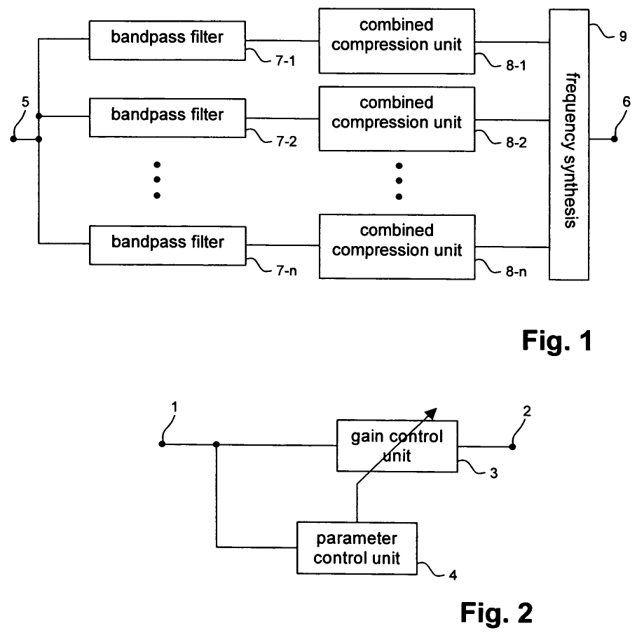

FIG. 1 shows a block diagram of a circuit arrangement for limiting the dynamic range of audio signals with a plurality of bandpass filters and downstream dynamic range control units;

FIG. 2 shows a block diagram of an embodiment of a dynamic range control unit for the circuit arrangement from FIG. 1.

FIG. 1 shows a block diagram of a circuit arrangement 1 for limiting the dynamic range of audio signals S, said circuit arrangement being routed by input 2 into a plurality of parallel bandpass filters 3a, 3b, . . . , 3n. The output of the bandpass filters 3a, 3b, . . . , 3n has a respective dynamic range control unit 4a, 4b, . . . , 4n connected to it which, in particular, may be a sufficiently well known automatic gain control unit AGC. Such automatic gain controllers per se are known from the prior art cited at the outset.

In this way, the audio signal S split into individual frequency bands has its dynamic range limited separately for each frequency band. The bandpass filters 3a, 3b, . . . , 3n should where possible cover the entire range of the relevant frequencies.

The audio signals whose dynamic range has been limited are supplied to a frequency synthesis unit 5 whose output 6 provides the output signal O.

FIG. 2 shows a block diagram of a dynamic range control unit 4 with an automatic gain control unit 7 which can be controlled using control parameter R. The input signal for the dynamic range control unit 4, which is applied to the input 8 and whose dynamic range is to be limited, is supplied firstly to the automatic gain control unit 7 and secondly to a unit 9 for ascertaining the instantaneous frequency. The design of the unit 9 for ascertaining the instantaneous frequency itself is sufficiently well known. A method for determining the instantaneous frequency, i.e. the audio signal's frequency which is currently present at the time of measurement and control, is described by way of example in Douglas J. Nelson “Cross-spectral methods for processing speech”, in: Journal of Acoustic Society of America, Vol. 110, No. 5, pt 1, November 2001, page 2577.

The instantaneous frequency is used as a control parameter R for the automatic gain control unit 7. In this case, the gain factor, the compression ratio and/or the adaptation time constant of the automatic gain controller 7 can be set individually or in combination by the instantaneous frequency.

The output 10 of the dynamic range control unit 4 then produces the audio signal with an optimally limited dynamic range, and this audio signal can then be processed further.

For the control, it is advantageous if the gain and compression of the audio signal are reduced by the automatic gain control unit 7 if the instantaneous frequency is outside of a stipulated range of values. The range of values itself can easily be determined through simulation or experiment depending on the respective application.

The method can be used for processing audio signals in hearing aids, for speech recognition or for other audio signal processing.

1. A method for limiting the dynamic range of audio signals (S), characterized by control of the dynamic range limiting on the basis of the instantaneous frequency of the audio signal (S) which is to be compressed as a control parameter.

2. The method as claimed in claim 1, characterized by control of a gain factor for an automatic gain controller for limiting dynamic range on the basis of the instantaneous frequency.

3. The method as claimed in claims 1, characterized by control of a compression ratio (Cᵥ) for an automatic gain controller on the basis of the instantaneous frequency.

4. The method as claimed in claim 1, characterized by control of an adaptation time constant for an automatic gain controller on the basis of the instantaneous frequency.

5. The method as claimed in claim 1, wherein adaptation time constants for limiting dynamic range are less than 20 ms.

6. The method as claimed in claim 1, characterized by parallel control of the dynamic range limiting for a plurality of band-limited audio signals (S).

7. A circuit arrangement (1) for limiting the dynamic range of audio signals (S) with at least one automatic dynamic range control unit (4), wherein at least one unit for ascertaining the instantaneous frequency for controlling the dynamic range limiting using the method as claimed in claim 1, on the basis of the ascertained instantaneous frequency is connected to at least one dynamic range control unit (4).

8. The circuit arrangement (1) as claimed in claim 7, characterized by a plurality of bandpass filters (3a, 3b, . . . , 3n) for the audio signal (S) whose dynamic range is to be limited and a respective automatic gain control unit (7) at the output of an associated bandpass filter (3a, 3b, . . . , 3n) and a respective unit for ascertaining the instantaneous frequency of the bandpass-filtered audio signal (S), where the unit for ascertaining the instantaneous frequency is coupled to the associated automatic gain control unit (7) in order to control the dynamic range limiting of the bandpass-filtered audio signal (S) on the basis of the instantaneous frequency of the bandpass-filtered audio signal (S) as a control parameter.

9. The circuit arrangement (1) as claimed in claim 8, characterized by a frequency synthesis unit (5) for combining the limited bandpass signals at the output (10) of the dynamic range control units (4).
